(19) United States
(12) Patent Application Publication
(10) Pub. No.: US 2025/0313962 A1
(43) Pub. Date: Oct. 9, 2025

(54) CORROSION-RESISTANT FILM FOR MAGNESIUM ALLOY WHEEL AND PREPARATION METHOD THEREOF

(71) Applicant: CITIC Dicastal Co., Ltd, Qinhuangdao (CN)

(72) Inventors: Shaokang Bian, Qinhuangdao (CN); Junfu Li, Qinhuangdao (CN); Mengnan Ma, Qinhuangdao (CN); Bitao Zhang, Qinhuangdao (CN); Zaide Wang, Qinhuangdao (CN); Lei Bao, Qinhuangdao (CN); Qian Ma, Qinhuangdao (CN); Lin Zhang, Qinhuangdao (CN)

(73) Assignee: CITIC Dicastal Co., Ltd, Qinhuangdao (CN)

(21) Appl. No.: 19/246,548

(22) Filed: Jun. 23, 2025

(30) Foreign Application Priority Data
Aug. 19, 2024 (CN) 202411139668.4

(51) Int. Cl. C23F 17/00; C23C 28/04

(52) U.S. Cl. CPC C23F 17/00; C23C 28/042

(57) ABSTRACT

Disclosed are a corrosion-resistant film for a magnesium alloy wheel and a preparation method thereof, The corrosion-resistant film for a magnesium alloy wheel includes: a micro-arc oxidation (MAO) coating, a chemically blocked coating, a physical vapor deposition (PVD) high-density inorganic hybrid coating, a high oxidation-resistant powder coating which are sequentially stacked from inside to outside by using the magnesium alloy wheel as a substrate. In the present disclosure, based on a micro-arc oxidation technology, zirconium, titanium, an iron salt, nano silicon, polymer resin are added into an electrolytic solution, and under a constant voltage mode of an adjustable power supply, the MAO coating is generated on the surface of the magnesium alloy wheel, followed by chemical blocking; the PVD high-density inorganic hybrid coating is obtained by coating on the chemically blocked coating, physical blocking is performed; the high oxidation-resistant powder coating is spray-coated on the PVD high-density inorganic hybrid coating.

### FIELD OF THE INVENTION

The present disclosure relates to the technical field of corrosion protection of magnesium alloy wheels, in particular to a corrosion-resistant film for a magnesium alloy wheel and a preparation method thereof.

### BACKGROUND OF THE INVENTION

A magnesium alloy is an alloy obtained by adding other elements to a metal magnesium matrix, and has the characteristics of small density, high specific strength and specific rigidity, good damping and shock absorption properties, strong electromagnetic shielding, excellent machinability, and easy recycling, and the like, and is about ⅔ of a weight of aluminum alloy. Magnesium alloy wheels has been used for more than 40 years, and the research and development and use of the magnesium alloy wheels can significantly reduce the self-weight of automobiles, reduce energy consumption, and achieve the purpose of energy saving and environmental protection. However, magnesium metal has poor corrosion resistance and wear resistance, and flammability, which seriously limits its use in automobile wheels. Therefore, seeking an anti-corrosion coating for magnesium alloy wheels and a preparation method thereof has become one of the technical problems to be solved urgently by those skilled in the art.

Therefore, for the problems existing in the prior art, by virtue of the active research and improvement by the designers of the present disclosure, provided in the present disclosure are a corrosion-resistant film for a magnesium alloy wheel and a preparation method thereof.

### SUMMARY OF THE INVENTION

A first object of the present disclosure is to provide a corrosion-resistant film for a magnesium alloy wheel in view of the defect in the prior art that magnesium metal has poor corrosion resistance and wear resistance, and flammability, which seriously limits its use in automobile wheels.

A second object of the present disclosure is to provide a method for preparing a corrosion-resistant film for a magnesium alloy wheel in view of the defect in the prior art that magnesium metal has poor corrosion resistance and wear resistance, and flammability, which seriously limits its use in automobile wheels.

In order to achieve the first object of the present disclosure, provided is a corrosion-resistant film for a magnesium alloy wheel, including: a micro-arc oxidation (MAO) coating, a chemically blocked coating, a physical vapor deposition (PVD) high-density inorganic hybrid coating, and a high oxidation-resistant powder coating which are sequentially stacked from inside to outside by using the magnesium alloy wheel as a substrate, wherein
the MAO coating is a magnesium oxide composite coating grown in situ, the magnesium oxide composite coating further contains nano zirconium, titanium, iron, and polymer resin, and the MAO coating has a thickness of 5-10 μm;
the chemically blocked coating is prepared by hybridizing the MAO coating in a chromium-free blocking solution;
the PVD high-density inorganic hybrid coating is a metal oxide thin film, the PVD high-density inorganic hybrid coating has a film thickness of 180-220 nm, and the metal oxide thin film contains at least one of niobium, chromium, nickel, titanium, zirconium, and tungsten; and
the high oxidation-resistant powder coating is prepared by using polyester resin as a resin material, using carbon black as a filler, and adding a matting agent, and the high oxidation-resistant powder coating has a film thickness of 80-100 μm.

Optionally, the corrosion-resistant film for a magnesium alloy wheel further includes: a colored paint and a highly transparent coating which are sequentially deposited on an outer surface of the high oxidation-resistant powder coating.

To achieve the second object of the present disclosure, the present disclosure provides a method for preparing a corrosion-resistant film for a magnesium alloy wheel, including:
performing Step S1: based on a micro-arc oxidation technology, adding zirconium, titanium, an iron salt, nano silicon, and polymer resin into an electrolytic solution, and under a constant voltage mode of an adjustable power supply, generating an MAO coating on a surface of the magnesium alloy wheel, wherein the MAO coating is a magnesium oxide composite coating grown in situ, and the magnesium oxide composite coating further contains nano zirconium, titanium, iron, and polymer resin;
performing Step S2: hybridizing the MAO coating in a chromium-free
blocking solution to achieve a chemically blocked coating;
performing Step S3: preparing a PVD high-density inorganic hybrid coating by adopting a PVD process; and
performing Step S4: generating a high oxidation-resistant powder coating on an outer surface of the PVD high-density inorganic hybrid coating by electrostatic spraying.

Optionally, the method for preparing the corrosion-resistant film for a magnesium alloy wheel further includes:

performing Step S5: sequentially depositing a colored paint and a highly transparent coating on an outer surface of the high oxidation-resistant powder coating by using an electrostatic spraying process.

Optionally, in the step S1, under the constant voltage mode of the adjustable power supply, a voltage is 300 V, the corresponding process time is 7 min, a frequency is 500 Hz, and a duty ratio is 6%.

Optionally, in the step S2, the MAO coating is hybridized in the chromium-free blocking solution to achieve the chemically blocked coating, and the chemically blocked coating is dried at 120° C. for 3 min.

Optionally, the step S3 further includes:
performing Step S31: removing a water vapor attached to a surface and micropores of the magnesium alloy wheel by infrared heating;
performing Step S32: performing plasma treatment, cleaning the surface of the magnesium alloy wheel, and performing surface modification; and
performing Step S33: preparing the PVD high-density inorganic hybrid coating by adopting the PVD process.

Optionally, the infrared heating is performed at a heating power of 3.9 KW for 30 s; the plasma treatment is performed at a power of 2 KW at an Ar flow rate of 400 sccm; when the PVD process is adopted, a background vacuum degree is 1.0×10⁻³ Pa, a vacuum degree of the process is 6.0×10⁻¹ Pa, a coating power is 10 KW, an Ar flow rate is 80 sccm, a flow rate of O₂ as a reaction gas is 120 sccm, and the sputtering time is 120 s; and a metal target material used in the PVD process is at least one of niobium, chromium, nickel, titanium, zirconium, and tungsten with a purity of greater than 99.95%.

Optionally, in the step S4, the high oxidation-resistant powder coating is generated on the outer surface of the PVD high-density inorganic hybrid coating by electrostatic spraying at a powder output rate of 60 g/min, a voltage of 50 KV, an electrostatic current of 50 μA, and a total gas flow rate of 5 MPa, and the high oxidation-resistant powder coating is baked at 170° C. for 15 min.

Optionally, in the step S5, the colored paint is baked at 140° C. for 20 min; and the highly transparent coating is cured at 170° C. for 15 min.

To sum up, according to the method for preparing the corrosion-resistant film for a magnesium alloy wheel in the present disclosure, based on the micro-arc oxidation technology, zirconium, titanium, the iron salt, nano silicon, and the polymer resin are added into the electrolytic solution, and under the constant voltage mode of the adjustable power supply, the MAO coating is generated on the surface of the magnesium alloy wheel, followed by chemical blocking; the PVD high-density inorganic hybrid coating is obtained by coating on the chemically blocked coating through PVD, and physical blocking is performed, improving adhesion between film layers and the anti-corrosion ability; and the high oxidation-resistant powder coating is spray-coated on the PVD high-density inorganic hybrid coating, and the MAO coating and chemically blocked coating are protected again, so that a corrosion-resistant wear-resistant coating for a magnesium alloy wheel with good adhesion and excellent corrosion-resistant properties is obtained on the magnesium alloy wheel.

### BRIEF DESCRIPTION OF DRAWINGS

FIG. 1 is a schematic structural diagram of a corrosion-resistant film for a magnesium alloy wheel according to the present disclosure; and

FIG. 2 is a flow chart of a method for preparing a corrosion-resistant film for a magnesium alloy wheel according to the present disclosure.

### DETAILED DESCRIPTION OF THE INVENTION

In order to explain the technical contents, structural features, achieved objects and effects of the present disclosure in detail, the present disclosure will be described below in detail with reference to the embodiments and the accompanying drawings.

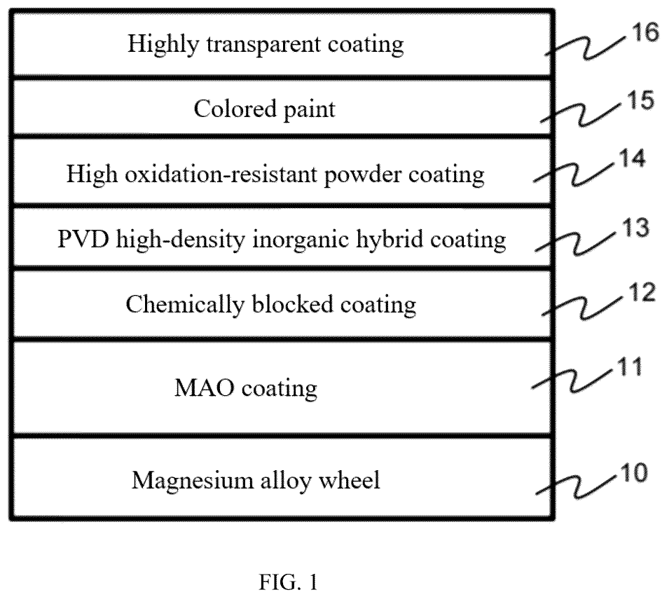

Referring to FIG. 1, FIG. 1 is a schematic structural diagram of a corrosion-resistant film for a magnesium alloy wheel according to the present disclosure. The corrosion-resistant film for a magnesium alloy wheel includes: a micro-arc oxidation (MAO) coating 11, a chemically blocked coating 12, a physical vapor deposition (PVD) high-density inorganic hybrid coating 13, and a high oxidation-resistant powder coating 14 which are sequentially stacked from inside to outside by using a magnesium alloy wheel 10 as a substrate, wherein
the MAO coating 11 is a magnesium oxide composite coating grown in situ, the magnesium oxide composite coating further contains nano zirconium, titanium, iron, and polymer resin, and the MAO coating 11 has a thickness of 5-10 μm;
the chemically blocked coating 12 is prepared by hybridizing the MAO coating 11 in a chromium-free blocking solution;
the PVD high-density inorganic hybrid coating 13 is a metal oxide thin film, the PVD high-density inorganic hybrid coating 13 has a film thickness of 180-220 nm, and the metal oxide thin film contains at least one of niobium, chromium, nickel, titanium, zirconium, and tungsten; and
the high oxidation-resistant powder coating 14 is prepared by using polyester resin as a resin material, using carbon black as a filler, and adding a matting agent, and the high oxidation-resistant powder coating 14 has a film thickness of 80-100 μm.

Preferably, the corrosion-resistant film for a magnesium alloy wheel further includes: a colored paint 15 and a highly transparent coating 16 which are sequentially deposited on an outer surface of the high oxidation-resistant powder coating 14.

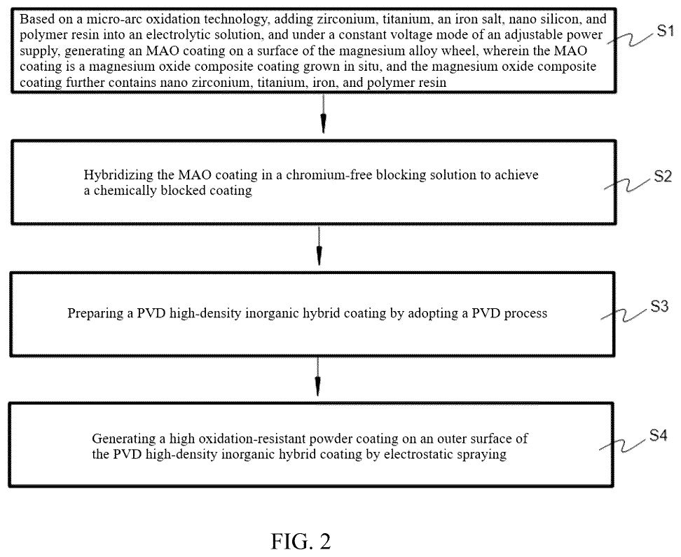

Referring to FIG. 2 and in conjunction with FIG. 1, FIG. 2 is a flow chart of a method for preparing a corrosion-resistant film for a magnesium alloy wheel according to the present disclosure. The method for preparing the corrosion-resistant film for a magnesium alloy wheel includes:
performing Step S1: based on a micro-arc oxidation technology, adding zirconium, titanium, an iron salt, nano silicon, and polymer resin into an electrolytic solution, and under a constant voltage mode of an adjustable power supply, generating an MAO coating 11 on a surface of a magnesium alloy wheel 10, wherein the MAO coating 11 is a magnesium oxide composite coating grown in situ, and the magnesium oxide composite coating further contains nano zirconium, titanium, iron, and polymer resin;
performing Step S2: hybridizing the MAO coating 11 in a chromium-free blocking solution to achieve a chemically blocked coating 12;
performing Step S3: preparing a PVD high-density inorganic hybrid coating 13 by adopting a PVD process, further achieving physical blocking; and
performing Step S4: generating a high oxidation-resistant powder coating 14 on an outer surface of the PVD high-density inorganic hybrid coating 13 by electrostatic spraying.

Preferably, the method for preparing the corrosion-resistant film for a magnesium alloy wheel further includes:

performing Step S5: sequentially depositing a colored paint 15 and a highly transparent coating 16 on an outer surface of the high oxidation-resistant powder coating 14 by using an electrostatic spraying process.

As a specific implementation, in the step S1, under the constant voltage mode of the adjustable power supply, a voltage is 300 V, the corresponding process time is 7 min, a frequency is 500 Hz, and a duty ratio is 6%.

In the step S2, the MAO coating 11 is hybridized in the chromium-free blocking solution to achieve the chemically blocked coating 12, and the chemically blocked coating 12 is dried at 120° C. for 3 min.

The step S3 further includes:
performing Step S31: removing a water vapor attached to a surface and micropores of the magnesium alloy wheel by infrared heating;
performing Step S32: performing plasma treatment, cleaning the surface of the magnesium alloy wheel, and performing surface modification; and
performing Step S33: preparing the PVD high-density inorganic hybrid coating 13 by adopting the PVD process.

The infrared heating is performed at a heating power of 3.9 KW for 30 s. The plasma treatment is performed at a power of 2 KW and an Ar flow rate of 400 sccm. When the PVD process is adopted, a background vacuum degree is 1.0×10⁻³ Pa, a vacuum degree of the process is 6.0×10⁻¹ Pa, a coating power is 10 KW, an Ar flow rate is 80 sccm, a flow rate of O₂ as a reaction gas is 120 sccm, and the sputtering time is 120 s. A metal target material used in the PVD process is at least one of niobium, chromium, nickel, titanium, zirconium, and tungsten with a purity of greater than 99.95%.

In the step S4, the high oxidation-resistant powder coating 14 is generated on the outer surface of the PVD high-density inorganic hybrid coating 13 by electrostatic spraying at a powder output rate of 60 g/min, a voltage of 50 KV, an electrostatic current of 50 μA, and a total gas flow rate of 5 MPa, and the high oxidation-resistant powder coating 14 is baked at 170° C. for 15 min.

In the step S5, in order to beautify the appearance and enhance protection, the colored paint 15 and the highly transparent coating 16 are sequentially deposited on the outer surface of the high oxidation-resistant powder coating 14. The colored paint 15 is baked at 140° C. for 20 min. The highly transparent coating 16 is cured at 170° C. for 15 min. The highly transparent coating 16 is one of a matte transparent powder or a high-gloss transparent powder.

In order to further highlight the prominent substantive features and notable progress of the present disclosure, the corrosion-resistant film for a magnesium alloy wheel obtained by the method for preparing the corrosion-resistant film for a magnesium alloy wheel of the present disclosure is subjected to corrosion resistance and wear resistance tests, the tests are all qualified, as shown in Table 1. Table 1 Corrosion resistance test and wear resistance test of a corrosion-resistant film for a magnesium alloy wheel

| | | Detection | Qualified |
|---|---|---|---|
| Detection item | Standard | device | or not |
| Tape adhesion | GMW14829: 2017 | Scribing knife | Qualified |
| test | | | |
| Neutral salt | GMW 3286: 2021, | (SF3600) salt | Qualified |
| spray test | and GMW 15282: | spray test | |
| | 2012 | chamber | |
| Copper | GMW14458: 2020, | (DBL-240NS) salt | Qualified |
| accelerated | and GMW 15282: | spray test | |
| acetic acid | 2012 | chamber | |
| salt spray | | | |
| Filiform | GMW14458: 2020, | (417522) Filiform | Qualified |
| test | and GMW15287: | test chamber | |
| | 2018, | | |
| High humidity | GMW14729: 2020 | (ZN-L500) | Qualified |
| test | | condensation water | |

To sum up, according to the method for preparing the corrosion-resistant film for a magnesium alloy wheel in the present disclosure, based on the micro-arc oxidation technology, zirconium, titanium, the iron salt, nano silicon, and the polymer resin are added into the electrolytic solution, and under the constant voltage mode of the adjustable power supply, the MAO coating is generated on the surface of the magnesium alloy wheel, followed by chemical blocking; the PVD high-density inorganic hybrid coating is obtained by coating on the chemically blocked coating through PVD, and physical blocking is performed, improving adhesion between film layers and the anti-corrosion ability; and the high oxidation-resistant powder coating is spray-coated on the PVD high-density inorganic hybrid coating, and the MAO coating and chemically blocked coating are protected again, so that a corrosion-resistant wear-resistant coating for a magnesium alloy wheel with good adhesion and excellent corrosion-resistant properties is obtained on the magnesium alloy wheel.

It will be understood by those skilled in the art that various modifications and variations can be made to the present disclosure without departing from the spirit or scope of the present disclosure. Thus, if any modifications or variations fall within the scope of protection of the appended claims and their equivalents, the present disclosure is deemed to encompass these modifications and variations.

What is claimed is:

1. A corrosion-resistant film for a magnesium alloy wheel, comprising: a micro-arc oxidation (MAO) coating, a chemically blocked coating, a physical vapor deposition (PVD) high-density inorganic hybrid coating, and a high oxidation-resistant powder coating which are sequentially stacked from inside to outside by using the magnesium alloy wheel as a substrate, wherein
the MAO coating is a magnesium oxide composite coating grown in situ, the magnesium oxide composite coating further contains nano zirconium, titanium, iron, and polymer resin, and the MAO coating has a thickness of 5-10 μm;
the chemically blocked coating is prepared by hybridizing the MAO coating in a chromium-free blocking solution;
the PVD high-density inorganic hybrid coating is a metal oxide thin film, the PVD high-density inorganic hybrid coating has a film thickness of 180-220 nm, and the metal oxide thin film contains at least one of niobium, chromium, nickel, titanium, zirconium, and tungsten; and
the high oxidation-resistant powder coating is prepared by using polyester resin as a resin material, using carbon black as a filler, and adding a matting agent, and the high oxidation-resistant powder coating has a film thickness of 80-100 μm.

2. The corrosion-resistant film for a magnesium alloy wheel according to claim 1, further comprising: a colored paint and a highly transparent coating which are sequentially deposited on an outer surface of the high oxidation-resistant powder coating.

3. A method for preparing the corrosion-resistant film for a magnesium alloy wheel according to claim 1, comprising:
performing Step S1: based on a micro-arc oxidation technology, adding zirconium, titanium, an iron salt, nano silicon, and polymer resin into an electrolytic solution, and under a constant voltage mode of an adjustable power supply, generating an MAO coating on a surface of the magnesium alloy wheel, wherein the MAO coating is a magnesium oxide composite coating grown in situ, and the magnesium oxide composite coating further contains nano zirconium, titanium, iron, and polymer resin;
performing Step S2: hybridizing the MAO coating in a chromium-free blocking solution to achieve a chemically blocked coating;
performing Step S3: preparing a PVD high-density inorganic hybrid coating by adopting a PVD process; and
performing Step S4: generating a high oxidation-resistant powder coating on an outer surface of the PVD high-density inorganic hybrid coating by electrostatic spraying.

4. The method for preparing the corrosion-resistant film for a magnesium alloy wheel according to claim 3, further comprising:
performing Step S5: sequentially depositing a colored paint and a highly transparent coating on an outer surface of the high oxidation-resistant powder coating by using an electrostatic spraying process.

5. The method for preparing the corrosion-resistant film for a magnesium alloy wheel according to claim 4, wherein in the step S1, under the constant voltage mode of the adjustable power supply, a voltage is 300 V, the corresponding process time is 7 min, a frequency is 500 Hz, and a duty ratio is 6%.

6. The method for preparing the corrosion-resistant film for a magnesium alloy wheel according to claim 4, wherein in the step S2, the MAO coating is hybridized in the chromium-free blocking solution to achieve the chemically blocked coating, and the chemically blocked coating is dried at 120° C. for 3 min.

7. The method for preparing the corrosion-resistant film for a magnesium alloy wheel according to claim 4, wherein the step S3 further comprises:
performing Step S31: removing a water vapor attached to a surface and micropores of the magnesium alloy wheel by infrared heating;
performing Step S32: performing plasma treatment, cleaning the surface of the magnesium alloy wheel, and performing surface modification; and
performing Step S33: preparing the PVD high-density inorganic hybrid coating by adopting the PVD process.

8. The method for preparing the corrosion-resistant film for a magnesium alloy wheel according to claim 7, wherein the infrared heating is performed at a heating power of 3.9 KW for 30 s; the plasma treatment is performed at a power of 2 KW at an Ar flow rate of 400 sccm; when the PVD process is adopted, a background vacuum degree is 1.0×10⁻³ Pa, a vacuum degree of the process is 6.0×10⁻¹ Pa, a coating power is 10 KW, an Ar flow rate is 80 sccm, a flow rate of O₂ as a reaction gas is 120 sccm, and the sputtering time is 120 s; and a metal target material used in the PVD process is at least one of niobium, chromium, nickel, titanium, zirconium, and tungsten with a purity of greater than 99.95%.

9. The method for preparing the corrosion-resistant film for a magnesium alloy wheel according to claim 4, wherein in the step S4, the high oxidation-resistant powder coating is generated on the outer surface of the PVD high-density inorganic hybrid coating by electrostatic spraying at a powder output rate of 60 g/min, a voltage of 50 KV, an electrostatic current of 50 μA, and a total gas flow rate of 5 MPa, and the high oxidation-resistant powder coating is baked at 170° C. for 15 min.

10. The method for preparing the corrosion-resistant film for a magnesium alloy wheel according to claim 4, wherein in the step S5, the colored paint is baked at 140° C. for 20 min; and the highly transparent coating is cured at 170° C. for 15 min.
